(19) United States
(12) Patent Application Publication
(10) Pub. No.: US 2011/0297215 A1
(43) Pub. Date: Dec. 8, 2011

(54) Manufacturing method and apparatus for a copper indium gallium diselenide solar cell

(75) Inventor: Roger J. Malik, Warren, NJ (US)

(73) Assignee: Roger J. Malik

(21) Appl. No.: 12/802,397

(22) Filed: Jun. 4, 2010

(51) Int. Cl. H01L 31/0264; H01L 21/06

(52) U.S. Cl. 136/255; 438/95; 257/E21.068; 257/E31.003

(57) ABSTRACT

A method to manufacture Copper Indium Gallium di Selenide (Cu(In,Ga)Se₂) thin film solar cell includes evaporating elemental Cu, In, Ga, and Se flux sources onto a heated substrate in a single vacuum system to form a non-intentionally doped Cu(In,Ga)Se₂ p-type conductivity layer and exposing the p-type conductivity layer to a thermally evaporated flux of Beryllium (Be) atoms to convert a surface layer of the p-type conductivity layer to an n-type conductivity layer resulting in a buried Cu(In,Ga)Se₂ p-n homojunction. Also, the source of Be atoms includes a circular rod of Be having a uniform cross-section that is resistively heated and having its temperature controlled by passing an electrical current through the rod.

### FIELD OF THE INVENTION

This invention relates to the field of thin-film solar cells and, more particularly, to a manufacturing method and apparatus for a copper indium gallium diselenide (Cu (In, Ga)Se₂) solar cell using a continuous in-vacuo deposition of semiconductor material forming the p-n junction and buffer layers.

### BACKGROUND OF THE INVENTION

The search for renewable energy sources that provide a long term and sustainable energy source for future generations of mankind while mitigating global warming trends associated with the burning of fossil fuels has received worldwide attention. One such renewable energy source, which may compete with current non-renewable energy sources is a solar cell. Solar cell usage is expected to grow substantially as the cost to manufacture solar cells decreases to a point where it may economically compete with current non-renewable energy sources. Thin film semiconductor deposition technology used in solar cell production has increased rapidly in recent years. Thin films of amorphous Si and polycrystalline CdTe and Cu(In,Ga)Se₂ layers can be deposited on a variety of low cost substrates including plate glass, metal foil, and even plastic films.

These semiconductor thin films can be monolithically integrated on the substrate resulting in higher voltage and current solar modules. One of the key advantages of thin film technology is that efficient solar spectrum absorption nearing 100% occurs in the direct bandgap semiconductor layers only a few microns in thickness thus reducing materials costs in these direct bandgap semiconductor layers. This is in contrast to crystalline silicon (Si) solar cells where the indirect bandgap semiconductor layers requires a minimum solar cell absorption layer thickness of a few hundred microns thus increasing materials costs in manufacturing. The manufacture of single crystal and polycrystalline Si wafers also requires high temperatures and energy consumption. Thus, the thin-film technology has an advantage over crystalline silicon in the energy payback period, which is defined as the time interval where the power output of the solar cell equals the energy input needed to manufacture, ship, and install the solar cells.

One promising thin film technology to emerge is based upon a chalcopyrite structured materials system with the chemical composition of Cuₓ(In_{y}Ga_{1-y})Se₂, which is commonly referred to as “CIGS”. CIGS has achieved high solar cell conversion efficiencies among the thin film technologies, with conversion efficiencies of 20% being achieved, in one illustrative example, at the U.S. National Renewable Energy Laboratories (NREL). Also unique to the CIGS chalcopyrite system is the existence of a very wide range of compositions over which CIGS is a good solar absorber wherein the

CIGS composition is Copper (“Cu”) deficient or x_{Cu}<1. Remarkably, CIGS polycrystalline semiconductor layers having a broad range of compositions may achieve equivalent solar cell conversion efficiencies as the best single crystal Si p-n homojunction solar cells. At higher Cu concentrations with x_{Cu}>1, the CIGS films become metallic in nature and make poor solar cells. The large composition range of CIGS is related to the semiconductor properties that arise from self-compensation mechanisms of intrinsic defects in the crystal structure. Cu vacancies, V_{Cu}, behave as shallow acceptors, which are compensated by In_{Cu} double donors. The activation energy to form V_{Cu} is very low and undoped CIGS grown layers are typically p-type with residual hole concentrations in the range of 1-30E15 cm⁻³.

A number of methods have been used to synthesize CIGS thin films to manufacture solar cells including thermal evaporation of the elements in vacuum, sputtering of individual metals layers followed by post deposition selenization using elemental Selenium (“Se”) or Hydrogen selenide (“H₂Se”) gases, electroplating from chemical baths, and atmospheric deposition of nanoparticle inks containing the CIGS elements followed by rapid thermal annealing to densify and recrystallize the deposited films into large grain sizes. Although it has been found possible to form small area solar cells with high efficiencies of 14-20% using any of these synthesis methods, it has been proven very difficult to scale-up these processes to large size substrates with widths of 100 cm or greater. This is principally caused from non-uniformities in the composition and thickness of the deposited CIGS films across the substrate. In addition, the chemistry to react Se with the metals is complicated and leads to various chemical reaction pathways and kinetics leading to inhomogeneous material with varying solar absorption characteristics. Interconnection of solar cells with varying open circuit voltage, V_{oc}, and short circuit current, I_{sc}, leads to degradation of the overall system solar conversion efficiency in large area solar modules (typically 0.6×1.2 m² deposited on a glass substrate) since ideally these diode parameters should be matched across the entire module.

The highest efficiency CIGS solar cells are typically made using vacuum deposition of the elements on soda lime glass substrates at a growth temperature of approximately 550 deg.C. It is conjectured that in the vacuum deposition process, the elements can directly react on the substrate surface resulting in a nearly homogeneous composition throughout the film. This contrasts with the two-stage process using sputter metal deposition followed by selenization, wherein the different metal diffusion coefficients and Se arrival rates lead to inhomogeneous CIGS p-n junction characteristics due to compositional variation. It is also thought that the natural diffusion of Sodium (Na) atoms out of the glass substrate helps to improve device efficiency without the need to add an extrinsic Na source in the deposition process. It has been empirically determined that Na doping of the CIGS films is required to achieve the highest solar conversion efficiencies with improvements of 50% seen by comparing side-by-side depositions on soda lime glass substrates with one substrate containing a Silicon DiOxide (“SiO₂”) diffusion barrier for Na. It is thought that Na may play a role to passivate dangling bond surface states at grain boundaries and at the critical p-n heterojunction formed between the p-type GIGS active layer and the wide bandgap n-type window layer that is typically made from Cadmium Sulfide (“CdS”). The reduction in solar cell efficiency is accompanied by a reduction in V_{oc} indicating that Fermi-level pinning may occur at the GIGS p-n heterojunction interface. The role of Na could be similar to that of H atoms, which are used to passivate dangling bonds at the SiO₂/Si oxide/semiconductor interface, which enables conductivity conversion in the key semiconductor technology of Complementary Metal Oxide Semiconductor (“CMOS”) field effect transistors. Thus, there is a clear need for an improved GIGS n-type solar cell utilizing semiconductor elements having similar valence bonding properties to form a p-n junctions while having a low vapor pressure in order to reduce or eliminate residual contamination in films

### SUMMARY OF THE INVENTION

Generally, the invention provides an improved CIGS n-type solar cell by using an n-type element having similar valence bonding properties as Group II elements while having a low vapor pressure in order to reduce or eliminate residual contamination in films. The invention provides for the use of a thermally-controlled Be doping source for n-type doping of CIGS that improves upon the conventional thin-film solar cells.

It is known that CIGS thin-films can be doped n-type using elemental evaporation of Zn atoms in a vacuum system. However, it is not deemed feasible to use Zinc (“Zn”) or Cadmium (“Cd”) atoms to produce CIGS p-n junctions in a vacuum system due to the exceedingly high vapor pressure of these elements. It is well known that Zn or Cd atoms introduced in a vacuum system will lead to persistent background pressures of these elements leading to residual contamination in films, which are not intentionally doped with these elements. Thus, the use of Zn or Cd evaporation would eventually contaminate the entire vacuum system leading to unintentional n-type doping of the entire

CIGS layer preventing CIGS solar cell manufacturing by vacuum evaporation. This is obvious from the high vapor pressures of Zn ˜10 Ton and Cd ˜100 Ton at a temperature of 600 deg. C. Therefore, excess Zn or Cd atoms will not be efficiently incorporated into CIGS films at typical growth temperatures of 550-575 deg. C and will contribute to background contamination in the vacuum system of these elements. The solution to the CIGS n-type doping problem via vacuum evaporation is to use an element with similar valence bonding properties as Group II elements but with a low vapor pressure. The only Group II element from the periodic chart of elements that satisfies this criteria is Be which forms the basis for the subject invention. The vapor pressure of Be is only ˜1×10⁻¹⁰ Torr at a deposition temperature of 600 deg. C and thus is an excellent candidate for use as a n-type dopant in CIGS using vacuum evaporation.

The use of a thermally-controlled Be doping source for n-type doping of CIGS has numerous advantages including the following:

1. Be can be used to n-type dope CIGS layer at a substrate growth temperature up to 600 deg. C since Be has essentially unity sticking coefficient at high temperatures.

2. Be evaporation is compatible in a Se background pressure environment used in CIGS vacuum deposition as evidenced by the successful growth of Zn(Mg,Be)Se compounds grown by Molecular Beam Epitaxy (MBE) used to fabricate high luminescence efficiency visible wavelength light emitting diodes and lasers.

3. The n-type doping concentration of Be in CIGS can be accurately controlled by controlling the temperature and resultant vapor pressure of a Be heated source.

4. The Be source can be simply implemented using a resistively heated Be rod to achieve uniform temperature and evaporation rates along the entire length of the rod.

5. The Be doped n-type CIGS layer will have a uniform donor concentration over large glass substrates leading to reproducible V_{oc} in the CIGS p-n homojunctions resulting in high module efficiencies.

6. Be atoms that are not deposited on the glass substrates will deposit on lower temperature thermal shields (typically made from stainless steel) surrounding the glass substrate and will not contribute to a persistent background pressure due to the low vapor pressure and unity sticking coefficient of Be.

7. In-situ formation of a CIGS p-n homojunction in a vacuum system eliminates the requirements for Chemical Bath Deposition of CdS buffer layers, which saves costs for chemicals, handling equipment and toxic waste disposal.

8. In-situ formation of the CIGS p-n homojunction eliminates possible contamination of the critical p-n junction with Oxygen (“O”) and Carbon (“C”), which is unavoidable when the CIGS layer is exposed to air before CdS buffer layer Chemical Bath Deposition.

9. n-type doping of CIGS layers with Be can be achieved at the same glass velocity as the CIGS deposition process thus increasing manufacturing throughput.

10. An optional buffer layer such as Indium Sulfide (“In₂S₃”), (In,Ga)₂Se₃, and other possible wide band gap compounds can be deposited on top of the CIGS p-n homojunction to protect the active CIGS films from sputter ion damage during the subsequent sputter deposition of the top ZnO n-type transparent contact layer.

11. Although Be is a toxic element and must be machined and handled using prescribed OSHA regulations, the total incorporated Be content in the CIGS solar cell is below 1 part-per-million by weight and therefore CIGS solar modules would be exempt from Restriction of Hazardous Substances Directive (“RoHS”) and Waste Electrical and Electronic Equipment regulations (“WEEE”).

Thus, it is one object of the invention is to provide a method to provide efficient n-type doping of CIGS solar cell films using Be as an elemental n-type dopant source.

Another object of the invention is to remove Cd containing compounds in CIGS solar cell modules since they are restricted by some countries due to environmental regulations including RoHS and WEEE.

Yet another object of the invention is to eliminate the cost and problems related to disposal of toxic Cd containing baths typically used to deposit CdS buffer layers in CIGS solar cells.

A further object of the invention is to provide a buried p-n homojunction in CIGS to avoid impurity contamination including O and C at the CIGS surface due to atmospheric exposure, which can degrade solar cell performance.

Yet another object of the invention is to improve V_{oc} and solar conversion efficiency by eliminating p-n junction interface recombination of electron-hole pairs at defect sites at the CIGS/buffer layer interface.

Another object of the invention is to form the entire solar active layer including p-n junction within a single vacuum system to reduce manufacturing costs and increase throughput.

A further object of the invention is to reduce or eliminate the need for Na doping of CIGS films to achieve high solar conversion efficiency.

Yet another object of the invention is to enable the growth of stacked p-n junctions in CIGS solar cells to improve solar conversion efficiency.

### BRIEF DESCRIPTION OF THE DRAWINGS

A further understanding of the invention can be obtained by reference to a preferred embodiment set forth in the illustrations of the accompanying drawings. Although the illustrated embodiment is merely exemplary of systems and methods for carrying out the invention, both the organization and method of operation of the invention, in general, together with further objectives and advantages thereof, may be more easily understood by reference to the drawings and the following description. The drawings are not intended to limit the scope of this invention, which is set forth with particularity in the claims as appended or as subsequently amended, but merely to clarify and exemplify the invention.

For a more complete understanding of the invention, reference is now made to the following drawings in which:

FIG. 1 is a sectional view illustrating an example of the configuration of a conventional CIGS solar cell with a CdS buffer layer formed by Chemical Bath Deposition;

FIG. 2 is a sectional view illustrating an example of a CIGS solar cell with a Be n-type dopant to form a buried p-n homojunction made in accordance with the preferred embodiment of the invention;

FIG. 3A is a side view of the Be doping source connected to a current controlled power supply for implementing CIGS n-type doping in accordance with an embodiment of the invention;

FIG. 3B is a sectional view of the Be circular rod shown in FIG. 3A, with a thermal heat shield and insulator in accordance with an embodiment of the invention; and

FIG. 4 is a schematic diagram of a CIGS vacuum deposition system using thermal elemental sources in accordance with an embodiment of the invention.

### DETAILED DESCRIPTION OF THE INVENTION

The invention may be understood more readily by reference to the following detailed description of preferred embodiment of the invention. However, techniques, systems and operating structures in accordance with the invention may be embodied in a wide variety of forms and modes, some of which may be quite different from those in the disclosed embodiment. Consequently, the specific structural and functional details disclosed herein are merely representative, yet in that regard, they are deemed to afford the best embodiment for purposes of disclosure and to provide a basis for the claims herein, which define the scope of the invention. It must be noted that, as used in the specification and the appended claims, the singular forms “a”, “an”, and “the” include plural referents unless the context clearly indicates otherwise.

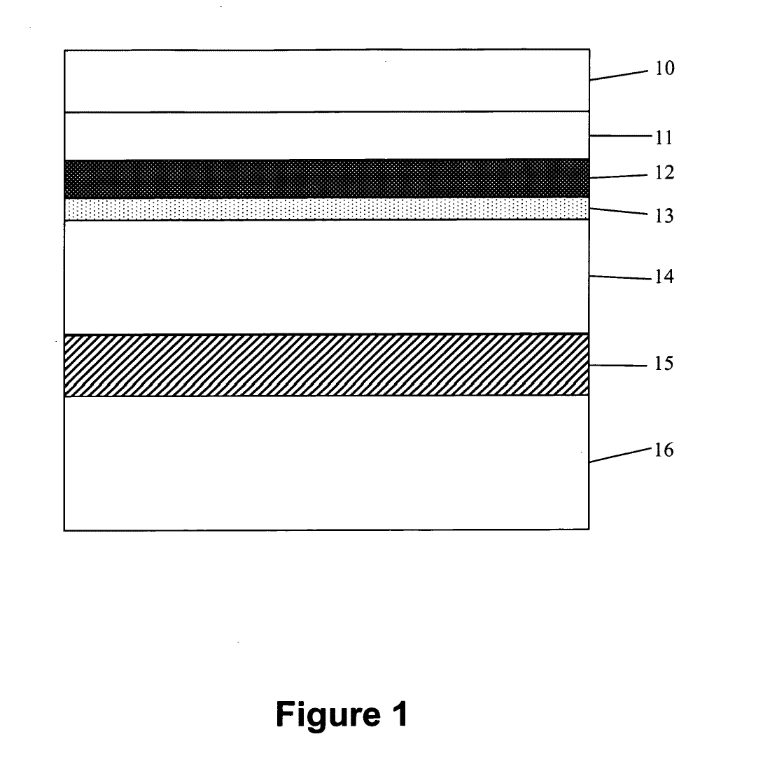

Referring to FIG. 1, there is shown a sectional view of a conventional prior art CIGS solar cell comprising a buffer layer deposited through a Chemical Bath Deposition. The device is fabricated on a substrate that may be typically be made of a glass material. In one example, a glass substrate 16 is used as a substrate to grow the thin film CIGS solar cell. First, a thin Mo layer 15 is sputtered on top of the glass to a thickness between 0.3-1 microns, which serves as the back electrical contact. Next, a thin CIGS layer 14 is grown by thermal evaporation in a vacuum system using heated elemental sources of Cu, In, Ga, and Se on top of the heated glass substrate at a temperature range between 400-600 deg. C and preferably at a temperature range of 550-575 deg. C. The thickness of the CIGS layer is typically between 1-2.5 microns in order to completely absorb the solar radiation at energies above the CIGS band gap. After the glass substrate is removed from the vacuum system and is exposed to air, a thin CdS buffer layer 12 having a thickness of 0.03-0.1 microns is deposited on the CIGS layer using Chemical Bath Deposition typically at a substrate temperature between 60-80 deg. C. It is known that the CdS serves as a wide band gap n-type window layer which is transparent to the majority of the solar radiation (CdS band gap=2.6 eV). In addition, the Chemical Bath Deposition also allows diffusion of Cd ions into the CIGS layer, which incorporate into Cu vacancies resulting in a doped n-type CIGS layer 13 at the CdS/CIGS heterojunction. Also known is that the inclusion of the CdS layer is not an essential element necessary to fabricate the

CIGS solar cell as the surface of the CIGS layer can be doped n-type simply by insertion in a partial electrolyte containing Cd or Zn ions which does not deposit a CdS layer on the CIGS surface. Additionally, the partial electrolyte p-n formation results in solar device efficiencies of ˜15%, which is comparable to those made with a deposited CdS buffer layer. After the CIGS p-n junction formation, a top contact is formed by sputter deposition of a ZnO n-type transparent conductive oxide layer 10. In some cases, an undoped ZnO layer 11 is first deposited before the ZnO n-type layer to help prevent leakage currents in the solar cell if the p-n junction formation does not completely cover the entire CIGS layer. Thus, it is evident that the inclusion of a CdS buffer layer is not an essential requirement in order to fabricate high efficiency CIGS solar cells. It would be very desirable to eliminate the need to deposit CdS buffer layers in the manufacturing process of CIGS solar cells for a number of reasons. Cd containing compounds are highly toxic and require expensive handling and disposal. Also, electronic products made with Cd compounds are restricted by some regulations including RoHS and WEEE. Some countries like Japan have actually banned electronic products containing Cd and CdS/CIGS solar modules cannot be sold there. In addition, the Chemical Bath Deposition process to deposit CdS is difficult to control with good thickness uniformity and complete coverage over large glass substrates used in CIGS module production. This directly results in reduced solar cell efficiencies and yields. Also, Chemical Bath Deposition is a relatively slow process resulting in a bottleneck in CIGS solar cell production and requires frequent replenishing and disposal of toxic chemicals used in the chemical bath. Further, the CdS deposition takes place on an air-exposed CIGS surface, which can lead to significant contamination by O and C, which can act as deep level recombination centers at the p-n heterojunction thus lowering solar cell efficiencies. Therefore an improved method to form p-n junctions is CIGS solar cells would be of great benefit to manufacturing throughput, reduce manufacturing costs, and comply with government regulations regarding toxic chemicals.

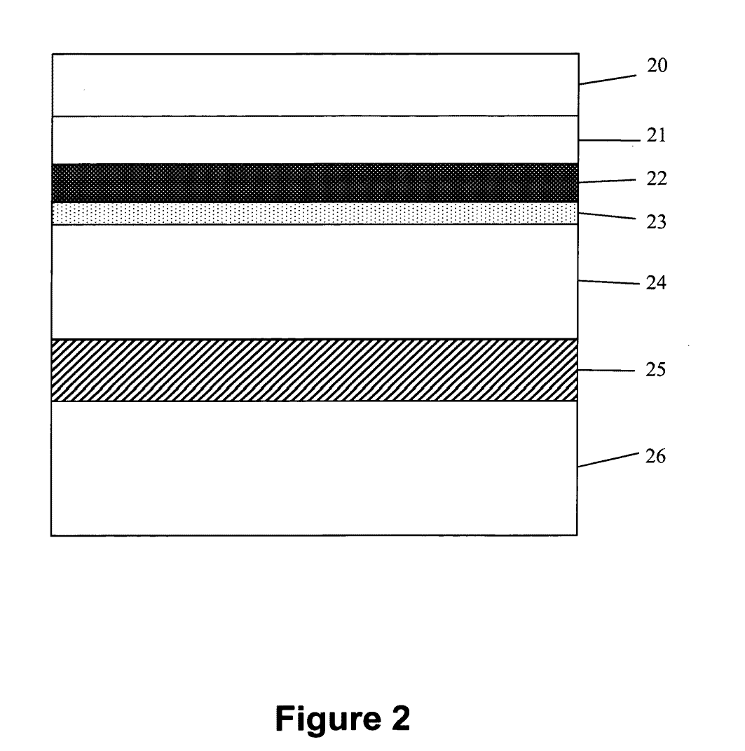

A cross-section of the vacuum deposited layers structure for the improved CIGS solar cell is shown in FIG. 2. A glass substrate 26 is used to deposit the stack of layers used to fabricate the CIGS solar cell. First, a thin Mo layer 25 is sputtered on top of the glass to a thickness between 0.3-1 microns, which serves as the back electrical contact. Next, a thin CIGS layer 24 is grown by thermal evaporation in a vacuum system using heated elemental sources of Cu, In, Ga, and Se on top of the heated glass substrate at a temperature between 400-600 deg. C and preferably at a temperature of 550-575 deg. C. The thickness of the CIGS layer is typically between 1-2.5 microns in order to completely absorb the solar radiation at energies above the CIGS band gap. In other non-limiting embodiments, other thin-film materials may be utilized, such as for example, Amorphous silicon, cadmium telluride, copper chalcogenide or other similar types of thin-film materials. Near the end of the CIGS deposition process, Be atoms are co-evaporated on top of the CIGS layer, which subsequently diffuse into and occupy Cu vacancies near the surface forming an n-type CIGS layer 23. It should be noted that a p-n homojunction is formed within the CIGS active layer and is free from chemical contamination by O or C atoms, which normally occurs from air exposure. Thus, it is anticipated that in vacuo formation of the CIGS p-n homojunction by practice of the invention will lead to improved electrical properties in the resultant solar cell due to reduced electron-hole interface recombination rates at the critical p-n junction. An optional wide band gap buffer layer 22 transparent to solar radiation may then be deposited on top of the CIGS p-n homojunction. In₂S₃, In₂Se₃, and other wide band gap compounds can be used for the optional buffer layer. The purpose of the wide band gap buffer layer is to prevent sputter radiation damage for the subsequently deposited ZnO n-type transparent contact layer 20. An optional undoped ZnO layer 21 may be inserted before the top contact layer in order to suppress electron injection into the CIGS layers and to provide edge electrical isolation between interconnected solar cell stripes comprising the solar module (not shown).

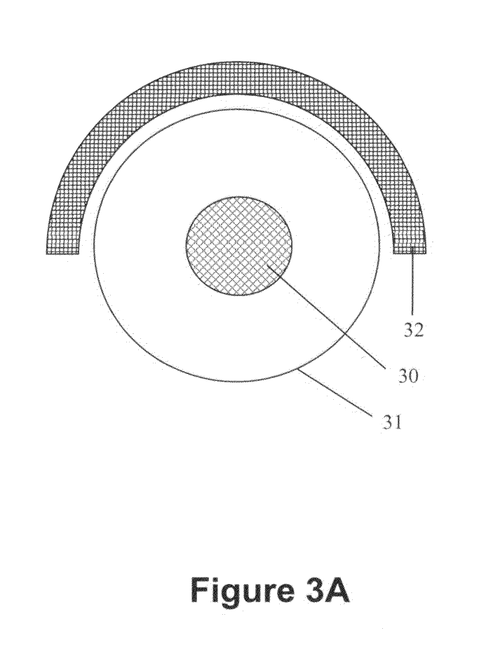

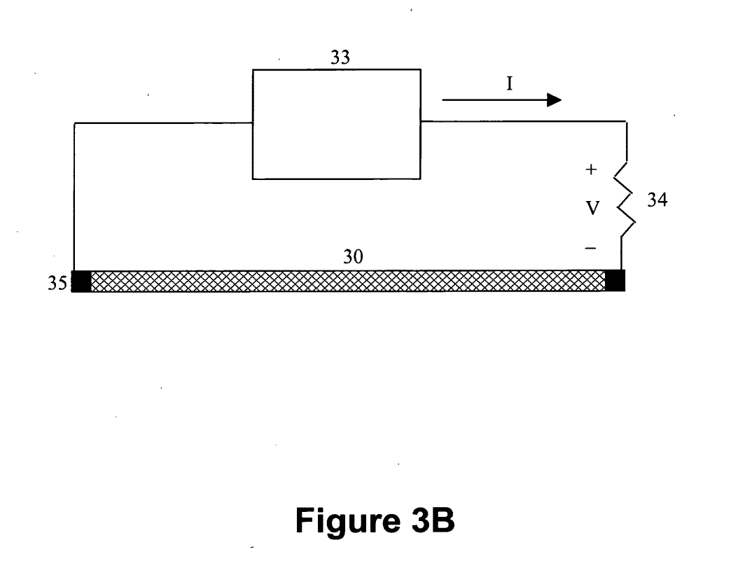

Referring to FIG. 3A, a method to achieve a thermally controlled Be doping source is shown. A Be rod 30 with uniform circular cross-section is resistively heated along its length to uniformly control the Be surface temperature and resultant evaporation rate of Be atoms upon the CIGS surface. A semi-circular multi-layer heat shield 32 made of, preferably, Mo or Ta is used to reflect heat back into the Be rod to make it more thermally efficient. The heat shields are spaced away and electrically isolated from the Be rod using annular ring insulators 31 preferably made from PBN.

A side view of the Be rod doping source is shown in FIG. 3B. Contact to the Be rod 30 is made by two end clamps 35, which are connected to an electrical power supply 33. The electrical current, I, used to heat the Be rod is monitored by the voltage drop across a precision calibrated milliohm resistor 34 inserted in series with the electrical circuit. The surface temperature of the Be rod can be controlled by regulating the current flow through it. In this manner, the Be doping of the CIGS layer can be precisely controlled and calibrated as a function of current flow through the Be rod. The axis of the Be rod is perpendicular to the direction of the glass motion through the inline vacuum system. The length of the Be rod and its height above the glass substrate are chosen such that the Be doping concentration in the CIGS layer across the width the glass substrate (perpendicular to glass motion) is essentially constant.

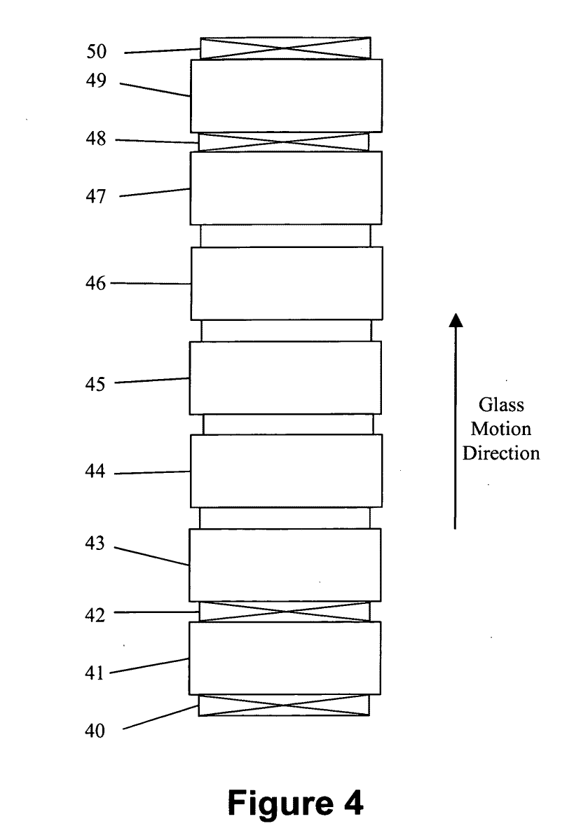

A schematic configuration of vacuum chambers for deposition of the CIGS solar cell active layers for the subject invention is shown in FIG. 4. An entry loadlock 41 for glass substrates is separated from atmosphere by a loading gate valve 40 and a vacuum isolation gate valve 42. After loading the glass substrate by a robotic handler (not shown), the entry loadlock is pumped down to high vacuum before opening the isolation gate valve 42 connecting the vacuum deposition chambers. The glass substrate temperature is raised to the desired starting deposition temperature of preferably 350-400 deg. C in the pre-heating chamber 43. The glass substrate then enters the CIGS deposition chamber 44 where the CIGS p-type active solar absorption layer is deposited.

The glass substrates move with constant velocity through all the vacuum deposition chambers separated by isolation gate valves 42 and 48. After CIGS deposition, the glass substrates enters the next vacuum chamber for Be evaporation 45 to convert the top surface of the CIGS layer to n-type by diffusion of Be atoms and incorporation into Cu vacancies. This step results in a buried p-n homojunction in the CIGS layer and avoids any contamination of the critical p-n junction region since it is performed in vacuo. After formation of the CIGS p-n homojunction, the glass substrates enter a vacuum chamber for the deposition of a wide band gap buffer layer 46 by vacuum evaporation. The preferred choices for the buffer layer include compounds comprised of a combination of In, Ga, S, and Se such as In₂S₃, (In,Ga)₂S₃, In₂Se₃, (In,Ga)₂Se₃, or (In,Ga)₂(S,Se)₃. It is desirable to avoid using buffer layers containing Group II elements including Zn and Cd to prevent any back diffusion of these high vapor pressure elements into the CIGS deposition chamber that could result in unintentional n-type doping in the CIGS absorption layer, which should remain p-type. After buffer layer deposition, the glass substrates move into another chamber 47, which allows cooling of the glass prior to unloading. An exit load lock 49 is isolated by a gate valve 48 from the vacuum deposition chambers and by a gate valve 50 on the air exit side. The glass substrate can be rapidly cooled in the exit load lock by introducing a flowing cooling gas such as N₂ or Ar. The glass substrates are removed from the exit load lock preferably using a robotic handler (not shown).

It should be noted that the entire process to form the CIGS p-type solar absorption layer, Be doped n-type CIGS layer forming the p-n homojunction, and the wide band gap solar transparent buffer layer operates at the same glass velocity throughout the inline vacuum deposition system. This directly results in a very high throughput process, which avoids process bottlenecks found in prior art CIGS processing steps thus reducing the cost of manufacturing. Also since all the deposition steps are performed in vacuum, it is expected that the layers will avoid contamination by trace impurities leading to improved solar module efficiencies. This should be compared to typical prior art processes wherein the CIGS layers experience residual contamination due to air exposure, for instance during the step for Chemical Bath Deposition of the CdS buffer layer.

While the present invention has been described with reference to one or more preferred embodiments, such embodiments are merely exemplary and are not intended to be limiting or represent an exhaustive enumeration of all aspects of the invention. The scope of the invention, therefore, shall be defined solely by the following claims. Further, it will be apparent to those of skill in the art that numerous changes may be made in such details without departing from the spirit and the principles of the invention. It should be appreciated that the present invention is capable of being embodied in other forms without departing from its essential characteristics.

1. A method to manufacture a thin film solar cell comprising:
evaporating a plurality of elemental flux sources onto a heated substrate in a single vacuum system to form a non-intentionally doped p-type conductivity layer;
exposing said p-type conductivity layer to a thermally evaporated flux of Beryllium (Be) atoms to convert a surface layer of said p-type conductivity layer to an n-type conductivity layer resulting in a buried p-n homojunction.

2. The method of claim 1, wherein said evaporated flux of Beryllium (Be)further comprising a circular rod of Beryllium, said circular rod having a uniform cross-section that is resistively heated and having a temperature controlled by passing an electrical current through it.

3. The method of claim 1, wherein said heated substrate is one of a flat rectangular glass plate, stainless steel foil, titanium foil, or a polymer film.

4. The method of claim 1, wherein said plurality of elemental flux sources further comprising flux exit apertures extending along a linear direction perpendicular to an axis of travel of said substrate.

5. The method of claim 1, wherein a direction of movement of said plurality of evaporated elemental flux sources is downward, upward, or sideways onto said heated substrate.

6. The method of claim 1, further comprising the step of depositing a wide band gap, undoped n-type conductivity buffer layer on said p-n homojunction.

7. The method of claim 6, wherein said undoped n-type conductivity buffer layer is selected from the group consisting of Indium (In), Gallium (Ga), Selenium (Se) and Sulphur (S).

8. The method of claim 7, wherein said n-type buffer layer is deposited on said single vacuum system without breaking vacuum.

9. The method of claim 1, wherein said plurality of elemental flux sources is selected from the group consisting of Copper (Cu), Indium (In), Gallium (Ga) and Selenium (Se).

10. The method of claim 1, wherein said p-type conductivity layer is Copper Indium Gallium diSelenide (Cu(In,Ga)Se₂).

11. A thin film solar cell comprising:
a substrate;
a Molybdenum contact layer deposited on said substrate;
a non-intentionally doped p-type layer formed on said contact layer;
a Beryllium (Be) layer doped on said p-type layer;
an undoped Zinc Oxide (ZnO) n-type layer deposited on said Beryllium layer; and
a doped Zinc Oxide (ZnO) n-type conductivity contact layer connected to said undoped Zinc Oxide layer.

12. The thin film solar cell of claim 9, wherein said non-intentionally doped p-type layer is selected from the group consisting of Copper Indium Gallium diSelenide (Cu(In,Ga)Se₂), Cadmium Telluride (CdTe) and Amorphous Silicon (a-Si).

13. The thin film solar cell of claim 9 further comprising a wide-band gap buffer n-type conductivity layer deposited on a p-n junction formed on said p-type layer.

14. The thin film solar cell of claim 11, wherein said wide band-gap n-type conductivity buffer layer is selected from the group consisting of Indium (In), Gallium (Ga), Selenium (Se) and Sulphur (S).

15. A method to manufacture Copper Indium Gallium diSelenide (Cu(In,Ga)Se₂) thin film solar cell comprising:
evaporating elemental Cu, In, Ga, and Se flux sources onto a heated substrate in a single vacuum system to form a non-intentionally doped Cu(In,Ga)Se₂ p-type conductivity layer; and
exposing said p-type conductivity layer to a thermally evaporated flux of Beryllium (Be) atoms to convert a surface layer of said p-type conductivity layer to an n-type conductivity layer resulting in a buried Cu(In,Ga)Se₂ p-n homojunction.

16. The method of claim 15, wherein said evaporated flux of Beryllium further comprising a circular rod of Beryllium, said circular rod having a uniform cross-section that is resistively heated and having a temperature controlled by passing an electrical current through it.

17. The method of claim 15, wherein said heated substrate is one of a flat rectangular glass plate, stainless steel foil, titanium foil, or a polymer film.

18. The method of claim 15, wherein said Cu, In, Ga, and Se elemental flux sources further comprising flux exit apertures extending along a linear direction perpendicular to an axis of travel of said substrate.

19. The method of claim 15, wherein a direction of movement of said plurality of evaporated elemental flux sources is downward, upward, or sideways onto said heated substrate.

20. The method of claim 15, further comprising the step of depositing a wide band gap, undoped n-type conductivity buffer layer on said p-n homojunction.
